(19) United States
(12) Patent Application Publication
(10) Pub. No.: US 2026/0101744 A1
(43) Pub. Date: Apr. 9, 2026

(54) SEMICONDUCTOR PACKAGE WITH BUMP STRUCTURE

(71) Applicant: Samsung Electronics Co., Ltd., Suwon-si (KR)

(72) Inventors: Myoungsoo KIM, Suwon-si (KR); Jisung KIM, Suwon-si (KR); Seongsik MIN, Suwon-si (KR)

(73) Assignee: Samsung Electronics Co., Ltd., Suwon-si (KR)

(21) Appl. No.: 19/065,530

(22) Filed: Feb. 27, 2025

(30) Foreign Application Priority Data
Sep. 20, 2024 (KR) 10-2024-0127354

(51) Int. Cl. H01L 23/00; H01L 21/66; H01L 23/528; H01L 23/538; H01L 25/18; H10D 80/30

(52) U.S. Cl. CPC H10W 20/43; H10W 20/435; H10D 80/30; H10P 74/273; H10W 70/611; H10W 72/0198; H10W 72/334; H10W 74/15; H10W 90/00; H10W 90/401; H10W 90/722; H10W 90/724; H10W 90/734

(57) ABSTRACT

A semiconductor package including: a base structure; a bump connected to the base structure; a chip connected to the bump; and a filling layer surrounding the bump, in which the chip includes: a substrate, an insulating structure between the substrate and the bump, a protective layer between the bump and the insulating structure, a conductive pad between the protective layer and the insulating structure, and a connection pattern penetrating the protective layer and connecting the bump and the conductive pad, and in which the filling layer comprises an interposed portion between the protective layer and the insulating structure.

### CROSS-REFERENCE TO RELATED APPLICATIONS

This U.S. non-provisional patent application claims priority under 35 U.S. C. § 119 of Korean Patent Application No. 10-2024-0127354, filed on Sep. 20, 2024, the entire contents of which are hereby incorporated by reference.

### BACKGROUND

The present disclosure herein relates to a semiconductor package, and more particularly, to a semiconductor package including a filling layer.

An integrated circuit chip is packaged into a semiconductor package to have a suitable form to be installed in an electronic device. In general, in a semiconductor package, a semiconductor chip is mounted on a printed circuit board, and the semiconductor chip and the printed circuit board are electrically connected to each other using bonding wires or bumps. Generally, to manufacture semiconductor process, a scribing process may be performed to cut a wafer to produce a plurality of semiconductor chips. However, since the scribing process is performed in a state in which a pad, a key pattern, etc., are arranged on a scribing lane, metal such as the pad, key pattern, etc., is cut in the scribing process, resulting in a burr being generated in the cut metal. With the development of electronics industry, various researches are carried out to improve the reliability of semiconductor packages.

### SUMMARY

The present disclosure provides a semiconductor package with improved electrical characteristics and reliability.

According to an aspect of the disclosure, a semiconductor package includes: a base structure; a bump connected to the base structure; a chip connected to the bump; and a filling layer surrounding the bump, in which the chip includes: a substrate, an insulating structure between the substrate and the bump, a protective layer between the bump and the insulating structure, a conductive pad between the protective layer and the insulating structure, and a connection pattern penetrating the protective layer and connecting the bump and the conductive pad, and in which the filling layer comprises an interposed portion between the protective layer and the insulating structure.

According to an aspect of the disclosure, a semiconductor package including: a base structure; a bump connected to the base structure; and a chip connected to the bump, in which the chip includes: a substrate, an insulating structure between the substrate and the bump, a protective layer between the bump and the insulating structure, a conductive pad between the protective layer and the insulating structure, and a connection pattern penetrating the protective layer and connecting the bump and the conductive pad, in which the protective layer comprises a first portion, and a second portion and a third portion spaced apart from each other with the first portion therebetween, in which a surface of the first portion of the protective layer is in contact with a surface of the insulating structure, in which a surface of the third portion of the protective layer is in contact with a surface of the conductive pad, and in which a surface of the second portion of the protective layer is spaced apart from the insulating structure and the conductive pad.

According to an aspect of the disclosure, a semiconductor package including: a base structure; a bump connected to the base structure; a chip connected to the bump; and a filling layer surrounding the bump, in which the chip includes: a substrate, an insulating structure between the substrate and the bump, a semiconductor device between the substrate and the insulating structure, a conductive via connected to the semiconductor device, a conductive pad in contact with the conductive via, a protective layer in contact with the insulating structure and the conductive pad, and a connection pattern penetrating the protective layer and in contact with the bump and the conductive pad, in which the protective layer comprises a first portion in contact with a surface of the insulating structure and a second portion spaced apart from the insulating structure, and in which the filling layer includes: a first interposed portion in contact with a surface of the second portion of the protective layer, and a first connection portion in contact with a sidewall of the second portion of the protective layer.

### BRIEF DESCRIPTION OF DRAWING

The accompanying drawings are included to provide a further understanding of the present disclosure, and are incorporated in and constitute a part of this specification. The drawings illustrate embodiments of the present disclosure and, together with the description, serve to explain principles of the embodiments of the present disclosure. In the drawings:

FIG. 1A is a plan view of a semiconductor package according to some embodiments;

FIG. 1B is a cross-sectional view taken along line A-A′ of FIG. 1A;

FIG. 1C is a plan view of a chip of FIGS. 1A and 1B;

FIG. 1D is a cross-sectional view taken along line B1-B1′ of FIG. 1C;

FIG. 1E is a cross-sectional view taken along line C1-C1′ of FIG. 1C;

FIG. 1F is a cross-sectional view taken along line E1-E1′ of FIG. 1C;

FIGS. 2A, 2B, 2C, 2D, 2E, 3A, 3B, 3C, 4A, 4B, 4C, 5, 6, 7A, 7B, 7C, 8A, 8B and 8C are diagrams for describing a method for manufacturing a semiconductor package according to FIGS. 1A to 1F;

FIGS. 9A and 9B are enlarged cross-sectional views of a semiconductor package according to some embodiments;

FIG. 10 is a cross-sectional view of a semiconductor package according to some embodiments;

FIG. 11 is a cross-sectional view of a semiconductor package according to some embodiments; and

FIG. 12 is a cross-sectional view of a semiconductor package according to some embodiments.

### DETAILED DESCRIPTION

Hereinafter, a semiconductor package according to embodiments of the embodiments of the present disclosure and a method for manufacturing the same will be described in detail with reference to the drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

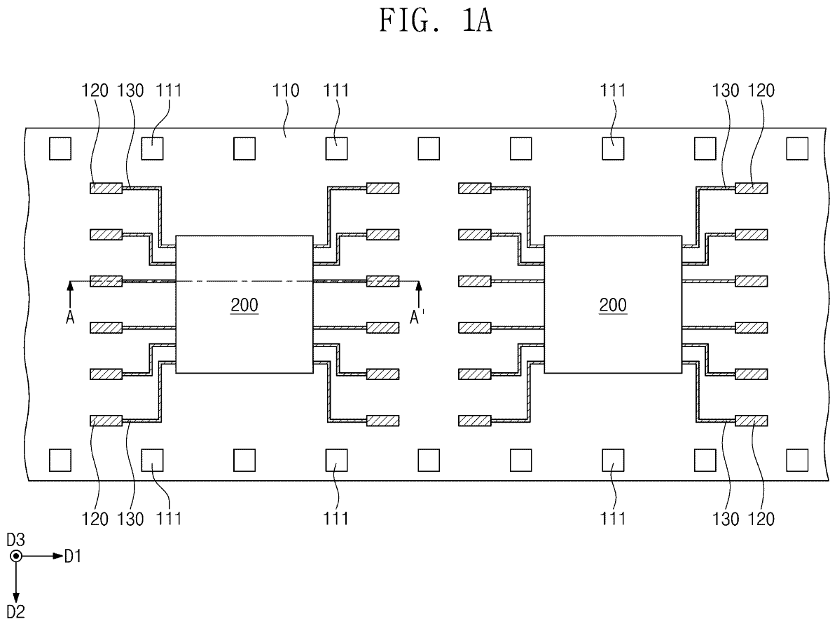

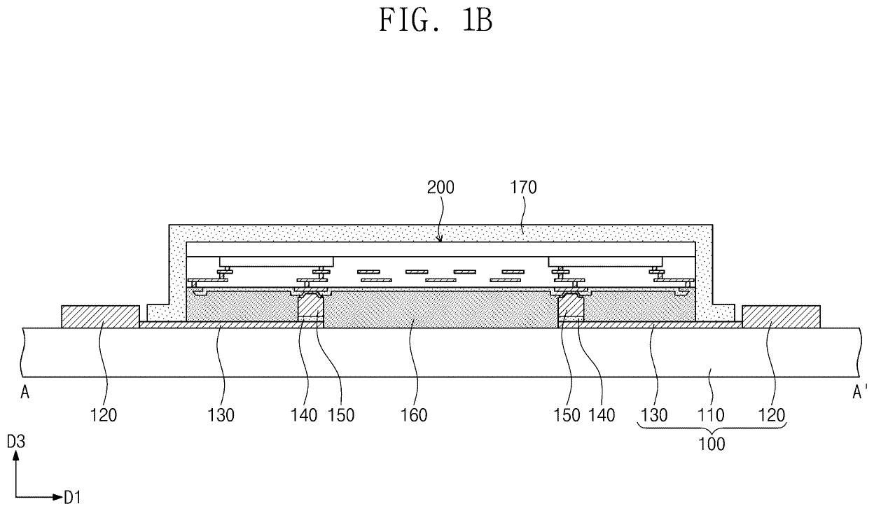

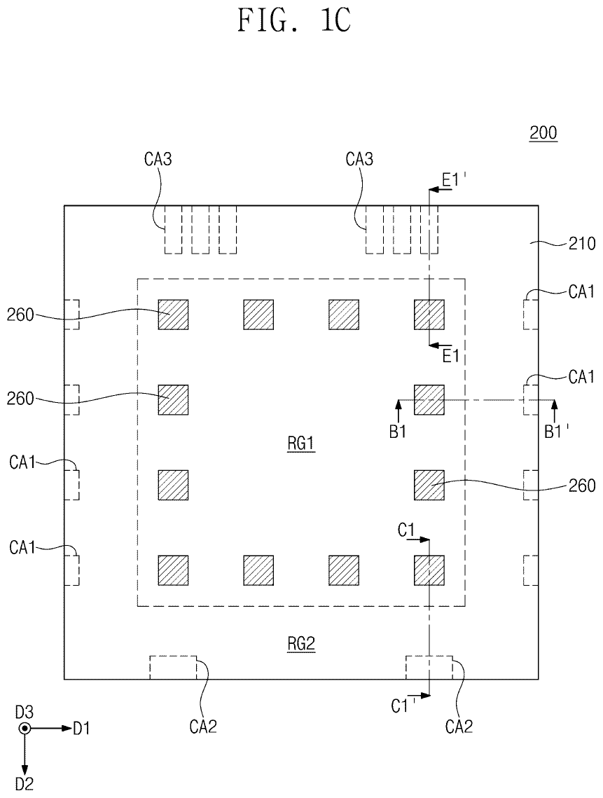

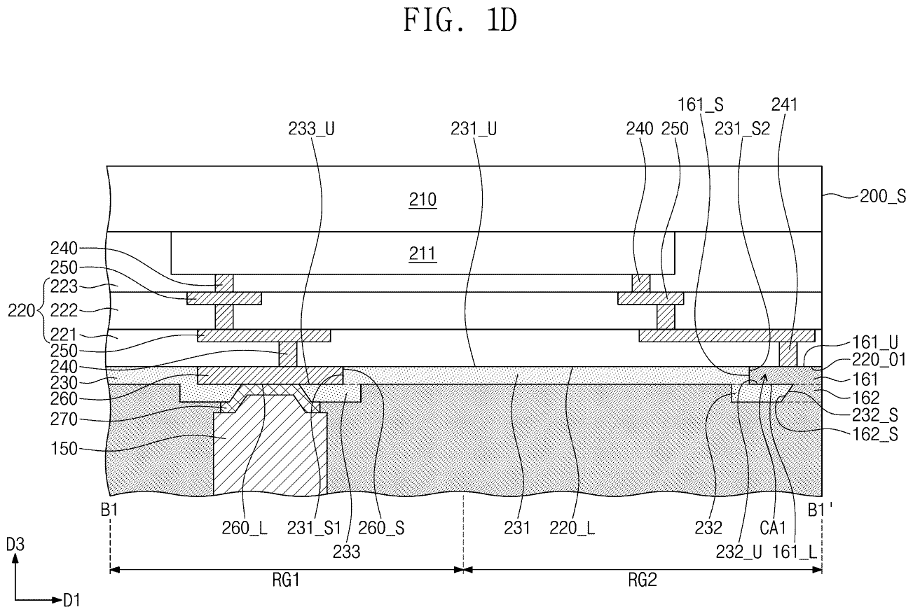

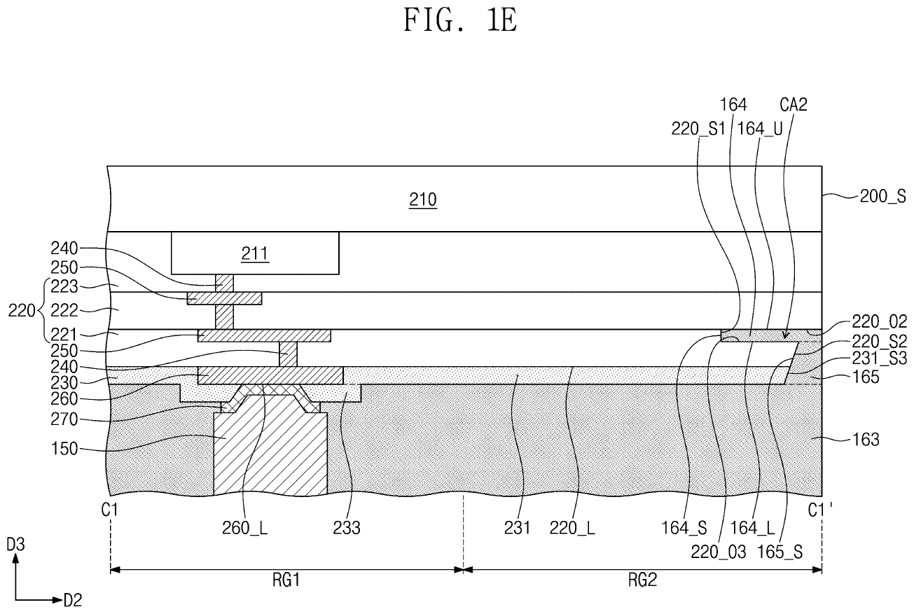

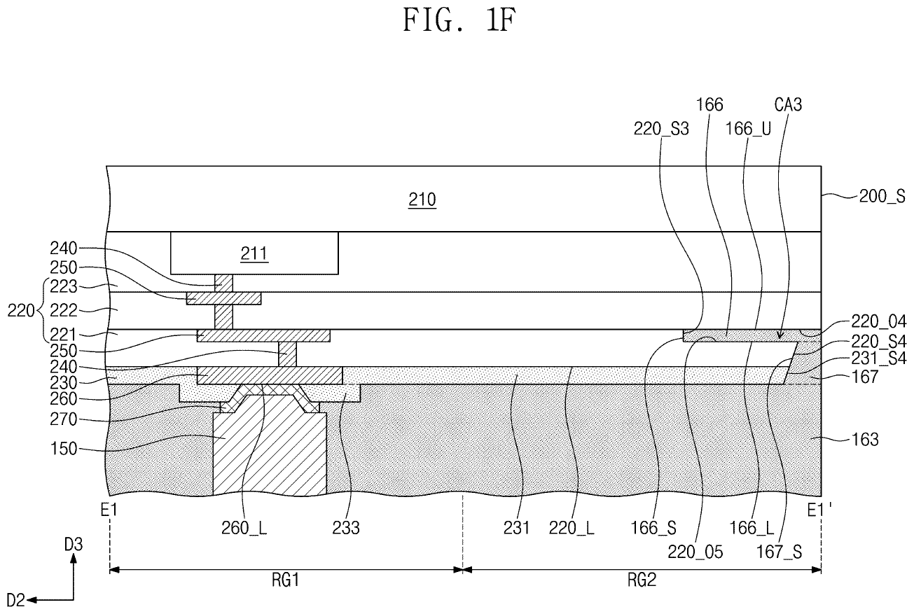

FIG. 1A is a plan view of a semiconductor package according to some embodiments. FIG. 1B is a cross-sectional view taken along line A-A′ of FIG. 1A. FIG. 1C is a plan view of a chip of FIGS. 1A and 1B. FIG. 1D is a cross-sectional view taken along line B1-B1′ of FIG. 1C. FIG. 1E is a cross-sectional view taken along line C1-C1′ of FIG. 1C. FIG. 1F is a cross-sectional view taken along line E1-E1′ of FIG. 1C.

Referring to FIGS. 1A and 1B, the semiconductor package may include a base structure 100. The base structure 100 may include a base substrate 110, connection pads 120, and connection lines 130.

The connection pads 120 and connection lines 130 may be provided on the base substrate 110. The base substrate 110 may have a shape of a plate expanding along a plane defined by a first direction D1 and a second direction D2. The first direction D1 and the second direction D2 may intersect each other. For example, the first direction D1 and the second direction D2 may be horizontal directions perpendicular to each other. According to some embodiments, the base substrate 110 may be a film substrate. In this case, the base substrate 110 may include a polymer material (e.g., polyimide). As understood by one of ordinary skill in the art, a film substrate is a foundation on which film components are built. Materials used for the film substrate may further include alumina, alumina nitride, sapphire, fused, ferrite, or any other suitable material known to one of ordinary skill in the art.

The base substrate 110 may include sprocket holes 111. The sprocket holes 111 may be arranged along the first direction D1. The sprocket holes 111 may be arranged in an edge of the base substrate 110. The sprocket holes 111 may penetrate the base substrate 110 in a third direction D3. The third direction D3 may intersect the first direction D1 and the second direction D2. For example, the third direction D3 may be a vertical direction perpendicular to the first direction D1 and the second direction D2.

The base substrate 110 may be wound or transferred using the sprocket holes 111. For example, pins of a transfer device may be inserted into the sprocket holes 111, and the base substrate 110 may be transferred as the pins move.

A chip 200 may be provided between the connection pads 120. The connection lines 130 may electrically connect the chip 200 and the connection pads 120. The connection pads 120 and the connection lines 130 may include a conductive material.

Adhesive patterns 140, bumps 150, filling layers 160, and cover layers 170 may be provided. The adhesive pattern 140 may be provided on the connection line 130. The adhesive pattern 140 may include a conductive material. For example, the adhesive pattern 140 may be an anisotropic conductive film (ACF).

The bump 150 may be provided on the adhesive pattern 140. The bump 150 may be electrically connected to the base structure 100. The bump 150 may be electrically connected to the connection line 130 of the base structure 100. The bump 150 may include a conductive material. For example, the bump 150 may include gold (Au). The connection line 130 of the base structure 100 may be electrically connected to the chip 200 through the adhesive pattern 140 and bump 150. As illustrated in FIGS. 1B and 1D, the bump 150 may include a raised portion defined by two inclined portions and a flat surface between the two inclined portions. However, as understood by one of ordinary skill in the art, the bump 150 is not limited to this configuration, and may be any suitable shape known to one of ordinary skill in the art.

The filling layer 160 may surround the bumps 150 and the adhesive patterns 140. The filling layer 160 may include an insulating material. For example, the filling layer 160 may include a polymer material.

The cover layer 170 may cover the chip 200 and the filling layer 160. The cover layer 170 may protect the chip 200. The cover layer 170 may include an insulating material. For example, the cover layer 170 may include a polymer material.

Referring to FIGS. 1C and 1D, the chip 200 may include a substrate 210, an insulating structure 220, a protective layer 230, conductive vias 240, conductive patterns 250, conductive pads 260, and connection patterns 270.

The substrate 210 may be a semiconductor substrate, an insulator substrate, or a semiconductor-on-insulator (SOI) substrate. For example, the semiconductor substrate may include silicon, germanium, silicon-germanium, gallium-phosphorus, or gallium-arsenic.

The substrate 210 may include a first region RG1 and a second region RG2. The first region RG1 and the second region RG2 may be regions divided in a plan view according to FIG. 1C. The second region RG2 may surround the first region RG1.

The insulating structure 220 may be provided between the substrate 210 and the bump 150. The insulating structure 220 may be in contact with a lower surface of the substrate 210. The insulating structure 220 may include a first insulating layer 221 being in contact with the protective layer 230, a second insulating layer 222 on the first insulating layer 221, and a third insulating layer 223 on the second insulating layer 222. As understood by one of ordinary skill in the art, the number of insulating layers included in the insulating structure 220 is not limited to the number of layers illustrated in the drawings, and may include any suitable number of insulating layers. According to some embodiments, the first to third insulating layers 221, 222, and 223 may each be a multilayer including a plurality of insulating layers. The second insulating layer 222 may be in contact with an upper surface of the first insulating layer 221 and may be spaced apart from the protective layer 230.

The first to third insulating layers 221, 222, and 223 may include an insulating material. For example, the first to third insulating layers 221, 222, and 223 may include an oxide.

A semiconductor device 211 may be provided between the insulating structure 220 and the substrate 210. The semiconductor device 211 may be, for example, a memory device, a logic device, or an image sensor device.

The conductive vias 240 and conductive patterns 250 may be surrounded by the insulating structure 220. The conductive vias 240 and conductive patterns 250 may be electrically connected to the semiconductor device 211. The conductive vias 240 and the conductive patterns 250 may include conductive materials having etch selectivity with respect to each other. For example, the conductive vias 240 may include tungsten (W), and the conductive patterns 250 may include aluminum (Al).

The conductive pads 260 may be in contact with a lower surface 220_L of the insulating structure 220. The lower surface 220_L of the insulating structure 220 may be a lower surface of the first insulating layer 221. The conductive pad 260 may be disposed between the insulating structure 220 and the protective layer 230. The conductive pad 260 may be in contact with the conductive via 240. The conductive pad 260 may be electrically connected to the semiconductor device 211 through the conductive vias 240 and conductive patterns 250. The conductive pads 260 may overlap the first region RG1 in the third direction D3. The conductive pads 260 may include a conductive material having etch selectivity with respect to a material included in the conductive vias 240. For example, the conductive pads 260 may include aluminum (Al).

The protective layer 230 may be in contact with the lower surface 220_L of the insulating structure 220, a sidewall 260_S of the conductive pad 260, and a lower surface 260_L of the conductive pad 260. The protective layer 230 may be provided between the bump 150 and the insulating structure 220. The protective layer 230 may surround the conductive pad 260. The protective layer 230 may include an insulating material different from that of the first to third insulating layers 221, 222, and 223 of the insulating structure 220. For example, the protective layer 230 may include a nitride. According to some embodiments, the protective layer 230 may include an oxide layer and a nitride layer.

The connection pattern 270 may be provided between the bump 150 and the conductive pad 260. The connection pattern 270 may be in contact with the bump 150. The connection pattern 270 may be in contact with the lower surface 260_L of the conductive pad 260. The connection pattern 270 may electrically connect the bump 150 and the conductive pad 260. The bump 150 may be electrically connected to the semiconductor device 211 through the connection pattern 270, the conductive pad 260, the conductive vias 240 and the conductive patterns 250. The connection pattern 270 may penetrate the protective layer 230. The connection pattern 270 may be surrounded by the protective layer 230. The connection pattern 270 may include a conductive material different from that of the conductive pad 260. For example, the connection pattern 270 may include at least one of gold (Au), titanium (Ti), or tungsten (W).

The protective layer 230 may include a first portion 231 being in contact with the lower surface 220_L of the insulating structure 220, a second portion 232 spaced apart from the insulating structure 220 and the conductive pad 260, and a third portion 233 being in contact with the lower surface 260_L of the conductive pad 260. An upper surface 231_U of the first portion 231 of the protective layer 230 may be in contact with the lower surface 220_L of the insulating structure 220. An upper surface 233_U of the third portion 233 of the protective layer 230 may be in contact with the lower surface 260_L of the conductive pad 260.

The second portion 232 of the protective layer 230 may be disposed at a lower level than the first portion 231 of the protective layer 230. In one or more examples, a distance in the third direction D3 between the second portion 232 of the protective layer 230 and the substrate 210 may be greater than a distance in the third direction D3 between the first portion 231 of the protective layer 230 and the substrate 210. The third portion 233 of the protective layer 230 may be disposed at a lower level than the first portion 231 of the protective layer 230. The second portion 232 and the third portion 233 of the protective layer 230 may be disposed at the same level. The second and third portions 232 and 233 of the protective layer 230 may be spaced apart from each other with the first portion 231 of the protective layer 230 therebetween. The first portion 231 of the protective layer 230 may include a first sidewall 231_S1 being in contact with the sidewall 260_S of the conductive pad 260.

A distance (e.g., a distance in the first direction D1) between the second portion 232 of the protective layer 230 and a sidewall 200_S of the chip 200 may be smaller than a distance (for example, a distance in the first direction D1) between the first portion 231 of the protective layer 230 and the sidewall 200_S of the chip 200. The distance (e.g., a distance in the first direction D1) between the second portion 232 of the protective layer 230 and the sidewall 200_S of the chip 200 may be smaller than a distance (e.g., a distance in the first direction D1) between the third portion 233 of the protective layer 230 and the sidewall 200_S of the chip 200. The sidewall 200_S of the chip 200 may include a sidewall of the substrate 210 and a sidewall of the insulating structure 220.

First cavities CA1, second cavities CA2, and third cavities CA3 of the chip 200 may be defined. The first cavity CA1 may be a space defined between the second portion 232 of the protective layer 230 and the first insulating layer 221 of the insulating structure 220. The second cavity CA2 may be a space defined between the first insulating layer 221 and the second insulating layer 222 of the insulating structure 220. The third cavity CA3 may be a space defined between the first insulating layer 221 and the second insulating layer 222 of the insulating structure 220. The first to third cavities CA1, CA2, and CA3 may overlap the second region RG2 in the third direction D3.

The filling layer 160 may include a first interposed portion 161, a first connection portion 162, and a lower portion 163. The first interposed portion 161 may be a portion interposed between the second portion 232 of the protective layer 230 and the first insulating layer 221 of the insulating structure 220. The first interposed portion 161 may be provided in the first cavity CA1.

A sidewall 161_S of the first interposed portion 161 may be in contact with a second sidewall 231_S2 of the first portion 231 of the protective layer 230. The second portion 232 of the protective layer 230 may include an upper surface 232_U being in contact with a lower surface 161_L of the first interposed portion 161. The insulating structure 220 may include a first surface 220_O1 being in contact with an upper surface 161_U of the first interposed portion 161. The first surface 220_O1 of the insulating structure 220 may be part of the lower surface 220_L of the insulating structure 220. The first surface 220_O1 of the insulating structure 220 may be part of a lower surface of the first insulating layer 221.

The first interposed portion 161 may be disposed at the same level as the conductive pad 260. A level of the upper surface 161_U of the first interposed portion 161 may be the same as a level of an upper surface of the conductive pad 260. A level of the lower surface 161_L of the first interposed portion 161 may be the same as a level of the lower surface 260_L of the conductive pad 260.

The conductive vias 240 may include a first conductive via 241 being in contact with the upper surface 161_U of the first interposed portion 161. A lower surface of the first conductive via 241 may be coplanar with the lower surface 220_L of the insulating structure 220. The lower surface of the first conductive via 241 may be coplanar with the first surface 220_O1 of the insulating structure 220.

The lower portion 163 of the filling layer 160 may be a portion surrounding the bump 150. The lower portion 163 of the filling layer 160 may be in contact with a lower surface of the first portion 231, a lower surface of the second portion 232, and a lower surface of the third portion 233 of the protective layer 230.

The first connection portion 162 may be a portion connecting the lower portion 163 and the first interposed portion 161 of the filling layer 160. The first connection portion 162 may be provided between the lower portion 163 and the first interposed portion 161 of the filling layer 160. The first connection portion 162 may be disposed at the same level as the second portion 232 of the protective layer 230. A sidewall 162_S of the first connection portion 162 may be in contact with a sidewall 232_S of the second portion 232 of the protective layer 230. The sidewall 162_S of the first connection portion 162 may be inclined with respect to the lower surface 220_L of the insulating structure 220. The sidewall 232_S of the second portion 232 of the protective layer 230 may be inclined with respect to the lower surface 220_L of the insulating structure 220. A width in the first direction D1 of the second portion 232 of the protective layer 230 may increase as a level of the second portion 232 of the protective layer 230 becomes higher. A width in the first direction D1 of the first connection portion 162 may decrease as a level of the first connection portion 162 becomes higher.

The upper surface 232_U of the second portion 232 of the protective layer 230 may be connected to the second sidewall 231_S2 of the first portion 231 of the protective layer 230 and the sidewall 232_S of the second portion 232 of the protective layer 230. The sidewall 161_S of the first interposed portion 161 may be connected to the upper surface 161_U and the lower surface 161_L of the first interposed portion 161. The sidewall 162_S of the first connection portion 162 may be connected to the lower surface 161_L of the first interposed portion 161.

Referring to FIGS. 1C and 1E, the filling layer 160 may further include a second interposed portion 164 and a second connection portion 165. The second interposed portion 164 may be a portion interposed between the first insulating layer 221 and the second insulating layer 222. The second interposed portion 164 may be provided in the second cavity CA2.

A sidewall 164_S of the second interposed portion 164 may be in contact with a first sidewall 220_S1 of the insulating structure 220. The first sidewall 220_S1 of the insulating structure 220 may be a sidewall of the first insulating layer 221. The insulating structure 220 may include a second surface 220_O2 being in contact with an upper surface 164_U of the second interposed portion 164 and a third surface 220_O3 being in contact with a lower surface 164_L of the second interposed portion 164. The second surface 200_O2 of the insulating structure 220 may be part of a lower surface of the second insulating layer 222. The third surface 220_O3 of the insulating structure 220 may be a surface of the first insulating layer 221.

The second interposed portion 164 may be disposed at the same level as the conductive pattern 250. A level of the upper surface 164_U of the second interposed portion 164 may be the same as a level of an upper surface of the conductive pattern 250. A level of the lower surface 164_L of the second interposed portion 164 may be the same as a level of a lower surface of the conductive pattern 250.

The second connection portion 165 may be a portion connecting the lower portion 163 and the second interposed portion 164 of the filling layer 160. The second connection portion 165 may be provided between the lower portion 163 and the second interposed portion 164 of the filling layer 160. The second connection portion 165 may be disposed at the same level as the first portion 231 of the protective layer 230 and the first insulating layer 221. The insulating structure 220 may include a second sidewall 220_S2 being in contact with a sidewall 165_S of the second connection portion 165. The first portion 231 of the protective layer 230 may include a third sidewall 231_S3 being in contact with the sidewall 165_S of the second connection portion 165.

The sidewall 165_S of the second connection portion 165, the second sidewall 220_S2 of the insulating structure 220, and the third sidewall 231_S3 of the first portion 231 of the protective layer 230 may be inclined with respect to the lower surface 220_L of the insulating structure 220. A width in the second direction D2 of the second connection portion 165 may decrease as a level of the second connection portion 165 becomes higher.

The third surface 220_O3 of the insulating structure 220 may be connected to the first sidewall 220_S1 and the second sidewall 220_S2 of the insulating structure 220. The sidewall 164_S of the second interposed portion 164 may be connected to the upper surface 164_U and the lower surface 164_L of the second interposed portion 164. The sidewall 165_S of the second connection portion 165 may be connected to the lower surface 164_L of the second interposed portion 164. The third sidewall 231_S3 of the first portion 231 of the protective layer 230 may be connected to the second sidewall 220_S2 of the insulating structure 220. The third sidewall 231_S3 of the first portion 231 of the protective layer 230 may be coplanar with the second sidewall 220_S2 of the insulating structure 220.

A distance in the third direction D3 between the second interposed portion 164 and the substrate 210 may be smaller than a distance in the third direction D3 between the first interposed portion 161 and the substrate 210.

Referring to FIGS. 1C and 1F, the filling layer 160 may further include a third interposed portion 166 and a third connection portion 167. The third interposed portion 166 may be a portion interposed between the first insulating layer 221 and the second insulating layer 222. The third interposed portion 166 may be provided in the third cavity CA3.

A sidewall 166_S of the third interposed portion 166 may be in contact with a third sidewall 220_S3 of the insulating structure 220. The third sidewall 220_S3 of the insulating structure 220 may be a sidewall of the first insulating layer 221. The insulating structure 220 may include a fourth surface 220_O4 being in contact with an upper surface 166_U of the third interposed portion 166 and a fifth surface 220_O5 being in contact with a lower surface 166_L of the third interposed portion 166. The fourth surface 220_O4 of the insulating structure 220 may be part of a lower surface of the second insulating layer 222. The fifth surface 220_O5 of the insulating structure 220 may be a surface of the first insulating layer 221.

The third interposed portion 166 may be disposed at the same level as the conductive pattern 250. A level of the upper surface 166_U of the third interposed portion 166 may be the same as a level of an upper surface of the conductive pattern 250. A level of the lower surface 166_L of the third interposed portion 166 may be the same as a level of a lower surface of the conductive pattern 250.

The third connection portion 167 may be a portion connecting the lower portion 163 and the third interposed portion 166 of the filling layer 160. The third connection portion 167 may be provided between the lower portion 163 and the third interposed portion 166 of the filling layer 160. The third connection portion 167 may be disposed at the same level as the first portion 231 of the protective layer 230 and the first insulating layer 221. The insulating structure 220 may include a fourth sidewall 220_S4 being in contact with a sidewall 167_S of the third connection portion 167. The first portion 231 of the protective layer 230 may include a fourth sidewall 231_S4 being in contact with the sidewall 167_S of the third connection portion 167.

The sidewall 167_S of the third connection portion 167, the fourth sidewall 220_S4 of the insulating structure 220, and the fourth sidewall 231_S4 of the first portion 231 of the protective layer 230 may be inclined with respect to the lower surface 220_L of the insulating structure 220. A width in the second direction D2 of the third connection portion 167 may decrease as a level of the third connection portion 167 becomes higher.

The fifth surface 220-05 of the insulating structure 220 may be connected to the third sidewall 220_S3 and the fourth sidewall 220_S4 of the insulating structure 220. The sidewall 166_S of the third interposed portion 166 may be connected to the upper surface 166_U and the lower surface 166_L of the third interposed portion 166. The sidewall 167_S of the third connection portion 167 may be connected to the lower surface 166_L of the third interposed portion 166. The fourth sidewall 231_S4 of the first portion 231 of the protective layer 230 may be connected to the fourth sidewall 220_S4 of the insulating structure 220. The fourth sidewall 231_S4 of the first portion 231 of the protective layer 230 may be coplanar with the fourth sidewall 220_S4 of the insulating structure 220.

A distance in the third direction D3 between the third interposed portion 166 and the substrate 210 may be smaller than a distance in the third direction D3 between the first interposed portion 161 and the substrate 210. The third interposed portion 166 may be disposed at the same level as the second interposed portion 164.

In the semiconductor package according to some embodiments, since the cavities CA1, CA2, and CA3 are filled with the interposed portions 161, 164, and 166 of the filling layer 160, a conductive pad or a conductive pattern may not be disposed at an edge of the chip 200. Accordingly, a phenomenon in which a burr is generated due to a conductive pad or a conductive pattern disposed at an edge of the chip 200 may be advantageously prevented or limited.

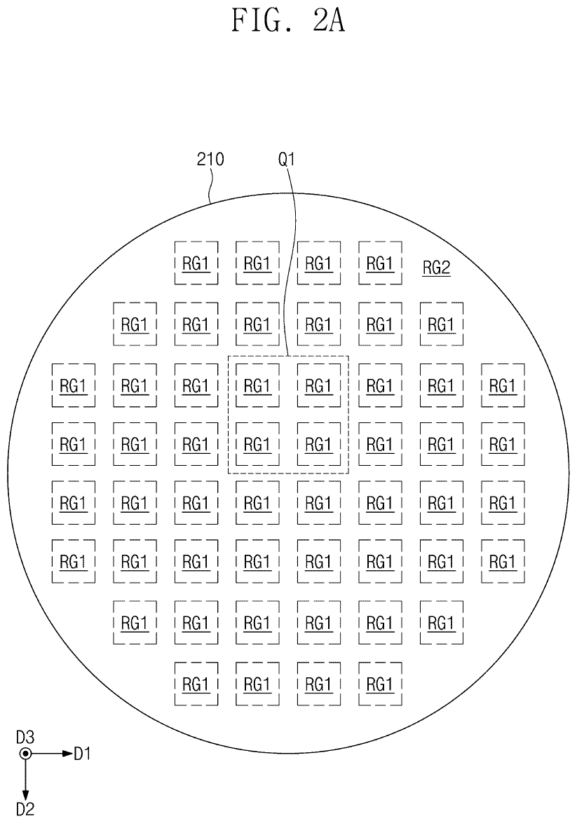

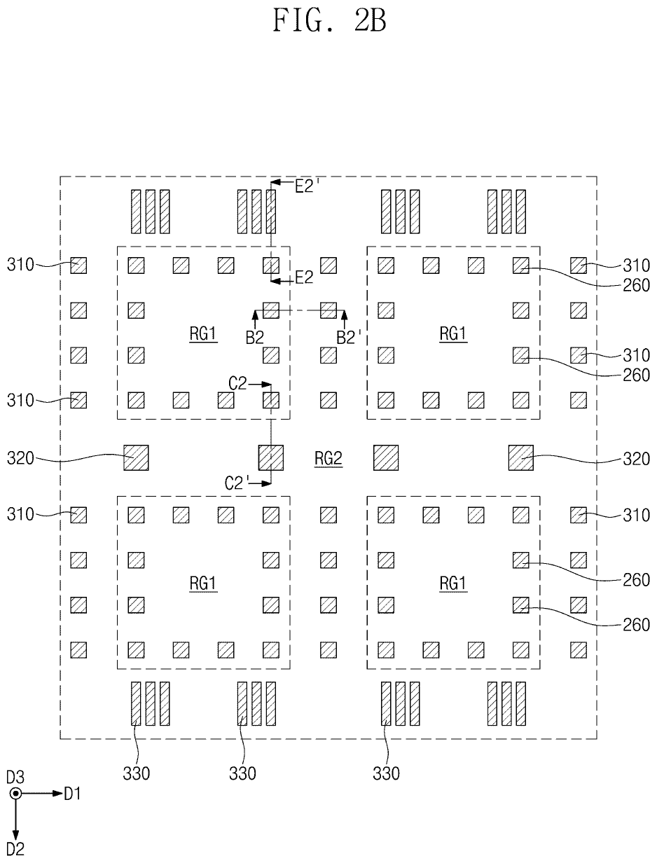

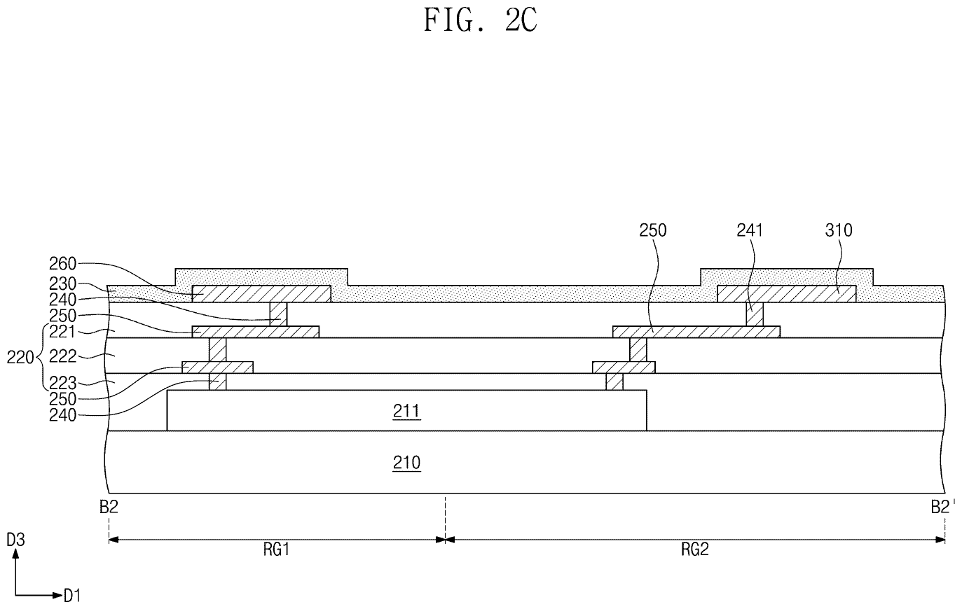

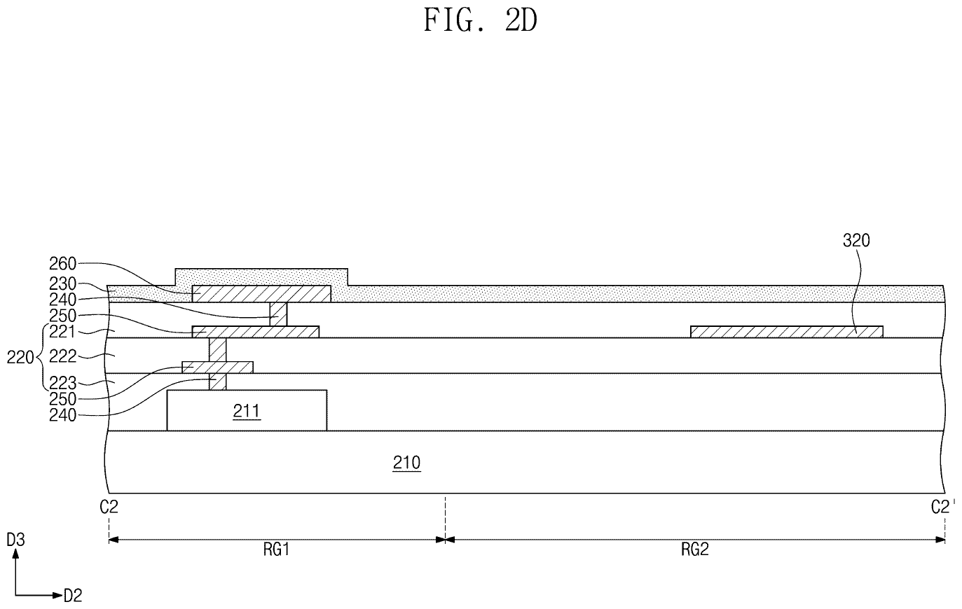

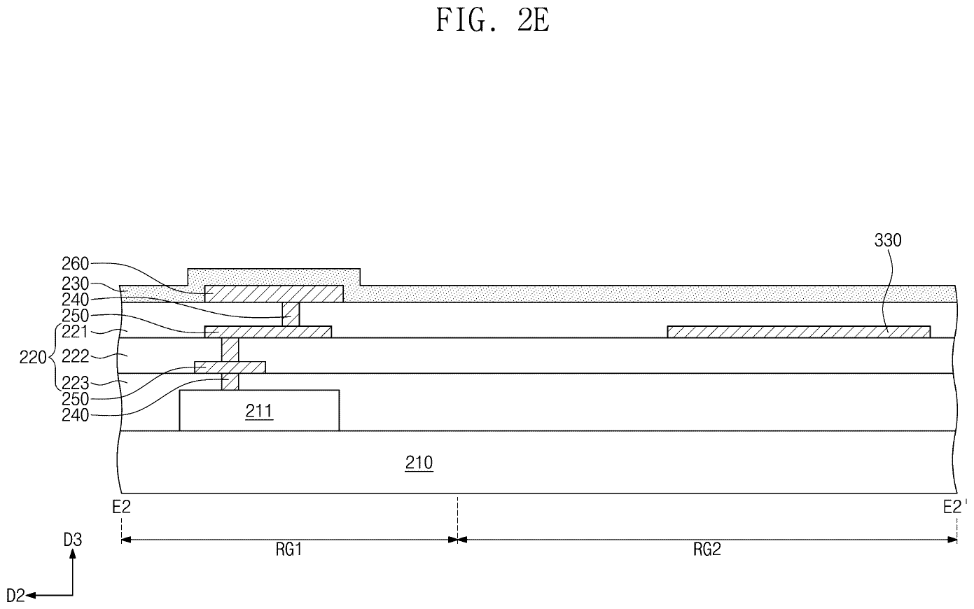

FIGS. 2A, 2B, 2C, 2D, 2E, 3A, 3B, 3C, 4A, 4B, 4C, 5, 6, 7A, 7B, 7C, 8A, 8B and 8C are diagrams for describing a method for manufacturing a semiconductor package according to FIGS. 1A to 1F. FIG. 2B is an enlarged view of region Q1 of FIG. 2A. FIG. 2C is a cross-sectional view taken along line B2-B2′ of FIG. 2B. FIG. 2D is a cross-sectional view taken along line C2-C2′ of FIG. 2B. FIG. 2E is a cross-sectional view taken along line E2-E2′ of FIG. 2B.

Referring to FIG. 2A, a substrate 210 may be provided. The substrate 210 may include first regions RG1 and a second region RG2. The first regions RG1 may be spaced apart from each other. The second region RG2 may surround the first regions RG1. For example, as illustrated in FIG. 2A, the second region RG2 is a continuous region that is located on portions of the substrate 210 where the first regions RG1 are not located.

Referring to FIGS. 2B, 2C, 2D, and 2E, semiconductor devices 211, first to third insulating layers 221, 222, and 223, respectively, of an insulating structure 220, conductive vias 240, conductive patterns 250, and conductive pads 260 may be formed on the substrate 210. The conductive pads 260 may overlap the first region RG1 in the third direction D3.

Test pads 310, measurement pads 320, and key patterns 330 may be formed. The test pads 310 may be formed at the same level as the conductive pads 260. The test pad 310 may be formed on the first insulating layer 221. The conductive vias 240 may include a first conductive via 241 being in contact with the test pad 310.

The measurement pads 320 and the key patterns 330 may be formed at the same level as the conductive pattern 250. The measurement pads 320 and the key patterns 330 may be formed between the first insulating layer 221 and the second insulating layer 222. According to some embodiments, the measurement pads 320 may be formed at the same level as the test pads 310.

The first insulating layer 221 may be formed after the measurement pad 320 is formed. A thickness of a portion, of the first insulating layer 221, overlapping the measurement pad 320 in the third direction D3 may be measured by using the measurement pad 320.

The key patterns 330 may be patterns for alignment of a photolithography process.

The test pads 310, the measurement pads 320, and the key patterns 330 may include a conductive material. The test pads 310, the measurement pads 320, and the key patterns 330 may include a conductive material having etch selectivity with respect to a conductive material included in the conductive via 240. For example, the test pads 310, the measurement pads 320, and the key patterns 330 may include aluminum (Al), and the conductive via 240 may include tungsten (W). The test pads 310, the measurement pads 320, and the key patterns 330 may overlap the second region RG2 in the third direction D3.

A protective layer 230 covering the conductive pads 260, the test pads 310, and the insulating structure 220 may be formed.

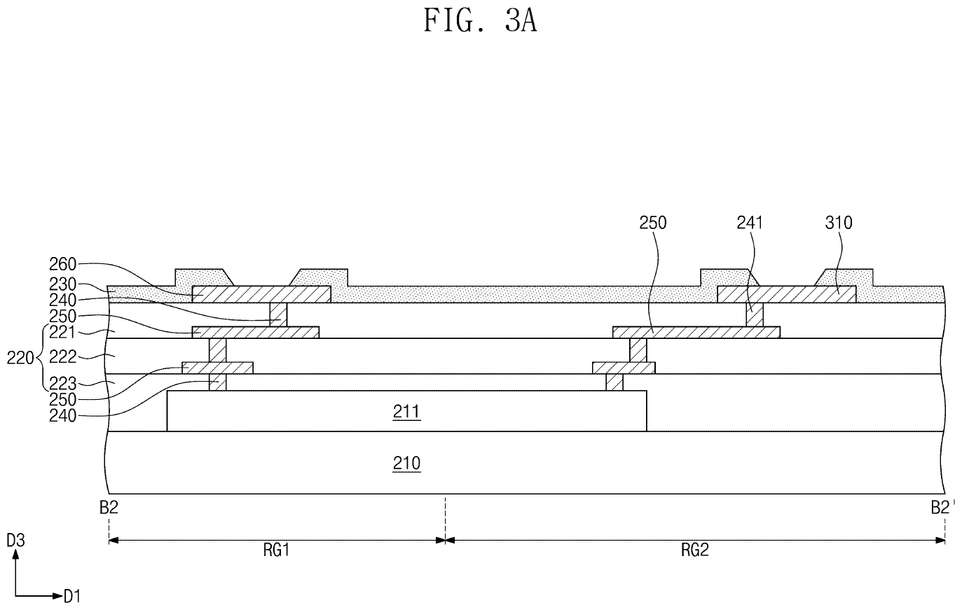

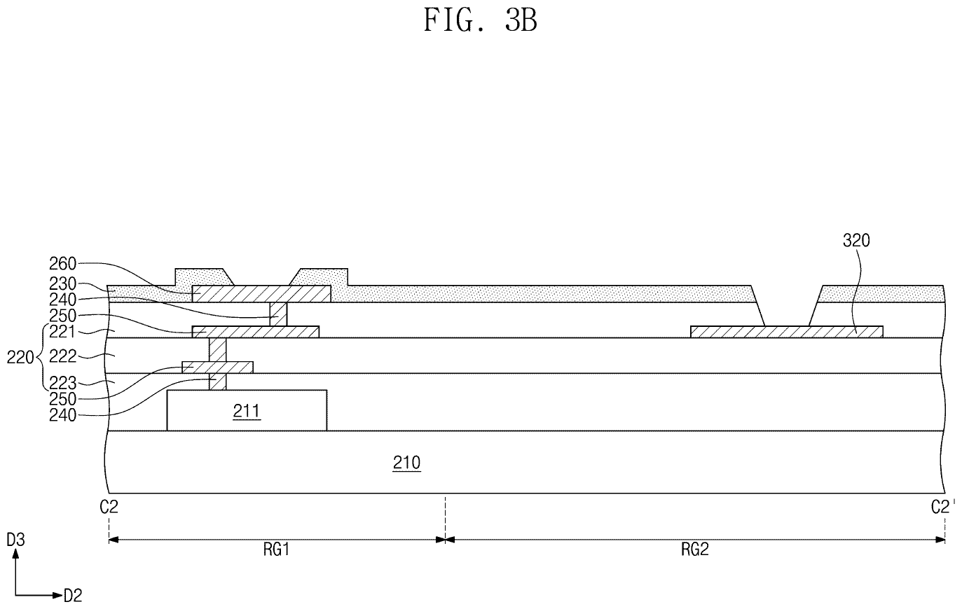

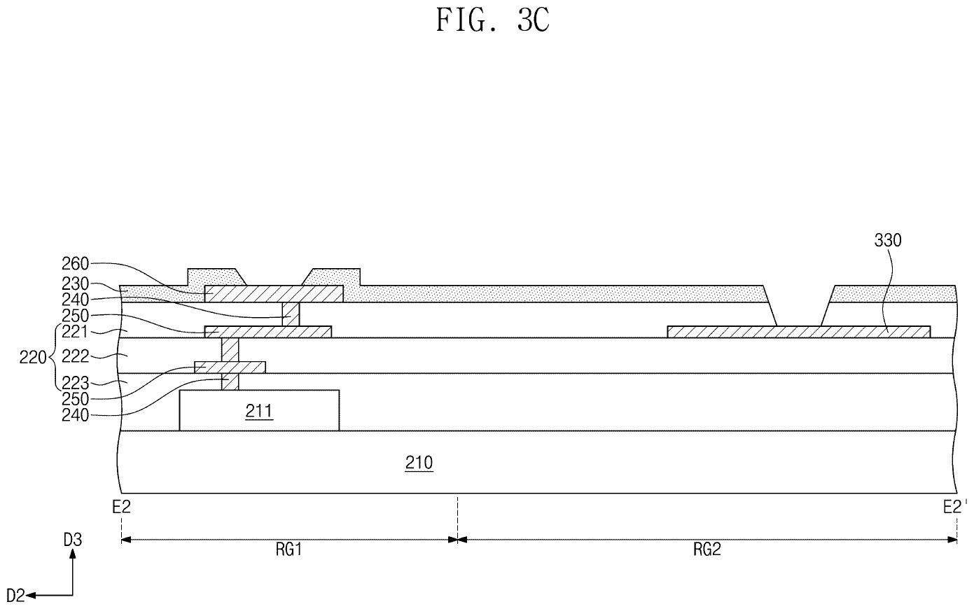

Referring to FIGS. 3A, 3B, and 3C, the protective layer 230 and the first insulating layer 221 may be etched. The conductive pad 260, the test pad 310, the measurement pad 320, and the key pattern 330 may be exposed by etching the protective layer 230 and the first insulating layer 221.

An electrical test of the semiconductor device 211 may be performed using the exposed test pad 310. The test pad 310 may be electrically connected to the semiconductor device 211 by the conductive vias 240 and the conductive patterns 250, and an electrical test of the semiconductor device 211 may be performed. According to some embodiments, a test of electrical performance of the semiconductor device 211 may be performed by bringing a test probe into contact with the test pad 310.

The second portion 232 (FIG. 1D) and the third portion 233 (FIG. 1D) of the protective layer 230 may be formed by etching the protective layer 230.

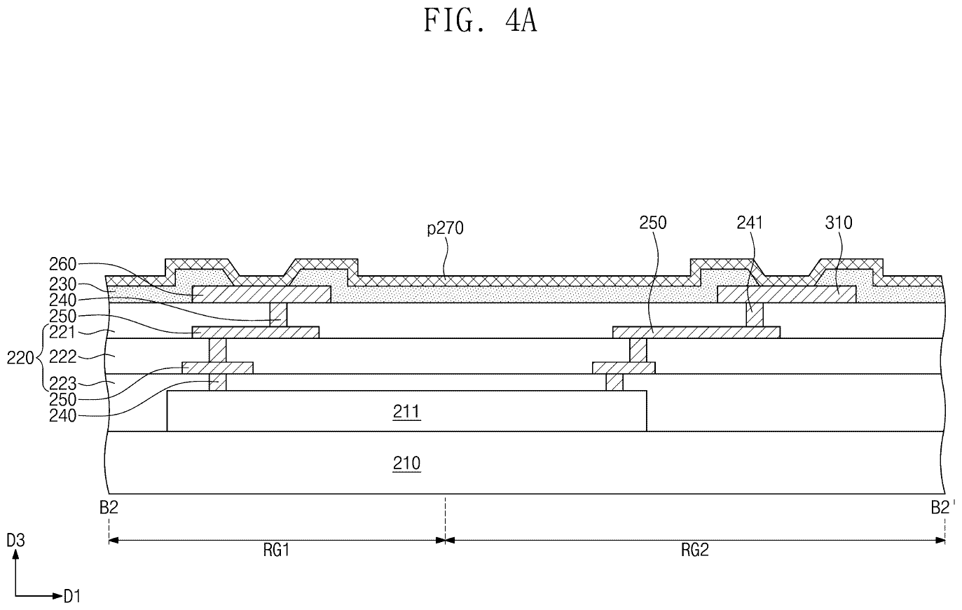

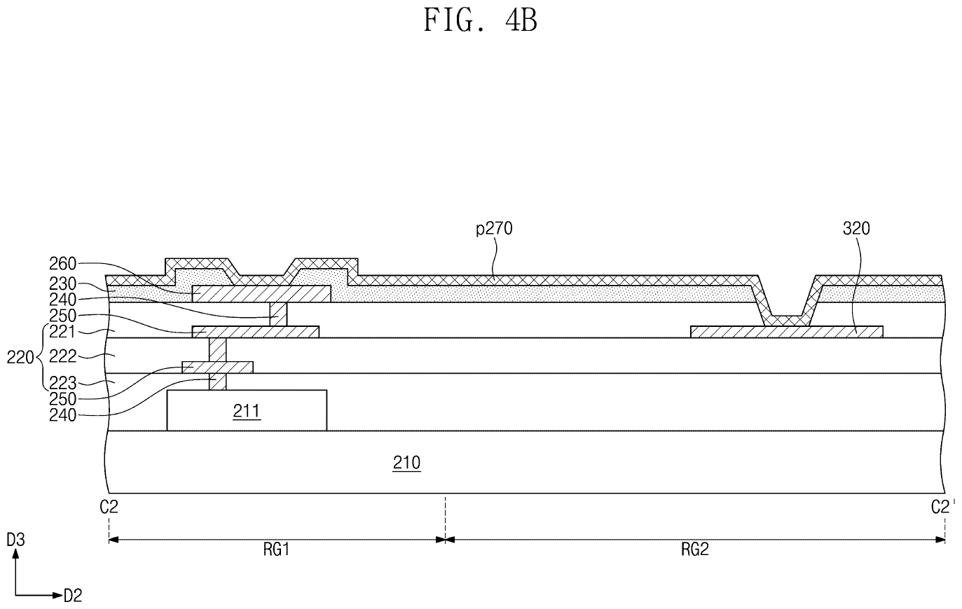

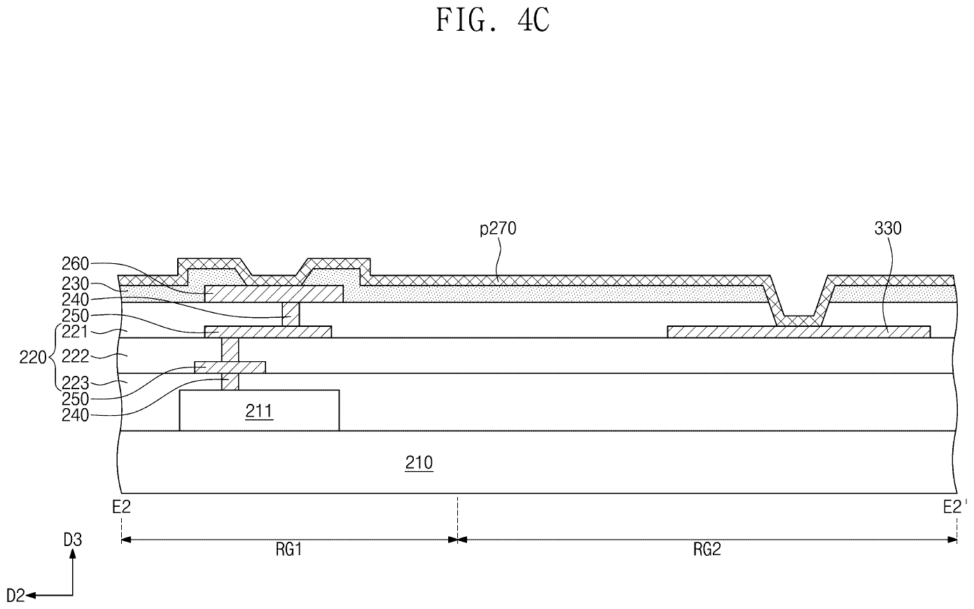

Referring to FIGS. 4A, 4B, and 4C, a preliminary connection layer p270 may be formed. The preliminary connection layer p270 may cover the protective layer 230, the conductive pad 260, the test pad 310, the measurement pad 320, the key pattern 330, and the first insulating layer 221. The preliminary connection layer p270 may be in contact with the protective layer 230, the conductive pad 260, the test pad 310, the measurement pad 320, the key pattern 330, and the first insulating layer 221. The preliminary connection layer p270 may include a conductive material having etch selectivity with respect to a conductive material included in the conductive pad 260, the test pad 310, the measurement pad 320, and the key pattern 330. For example, the preliminary connection layer p270 may include at least one of gold (Au), titanium (Ti), or tungsten (W).

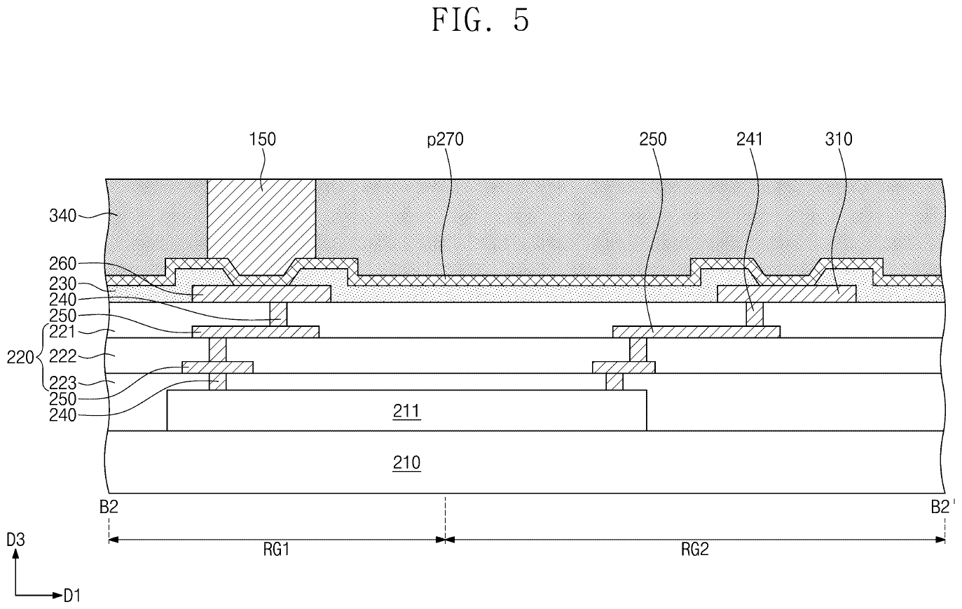

Referring to FIG. 5, a photoresist layer 340 may be formed on the preliminary connection layer p270. The photoresist layer 340 may include a photoresist material. The photoresist layer 340 may cover the preliminary connection layer p270.

A bump 150 may be formed in the photoresist layer 340. Forming the bump 150 may include forming an opening that exposes the preliminary connection layer p270 by patterning the photoresist layer 340, and forming the bump 150 in the opening. The bump 150 may overlap the conductive pad 260 in the third direction D3.

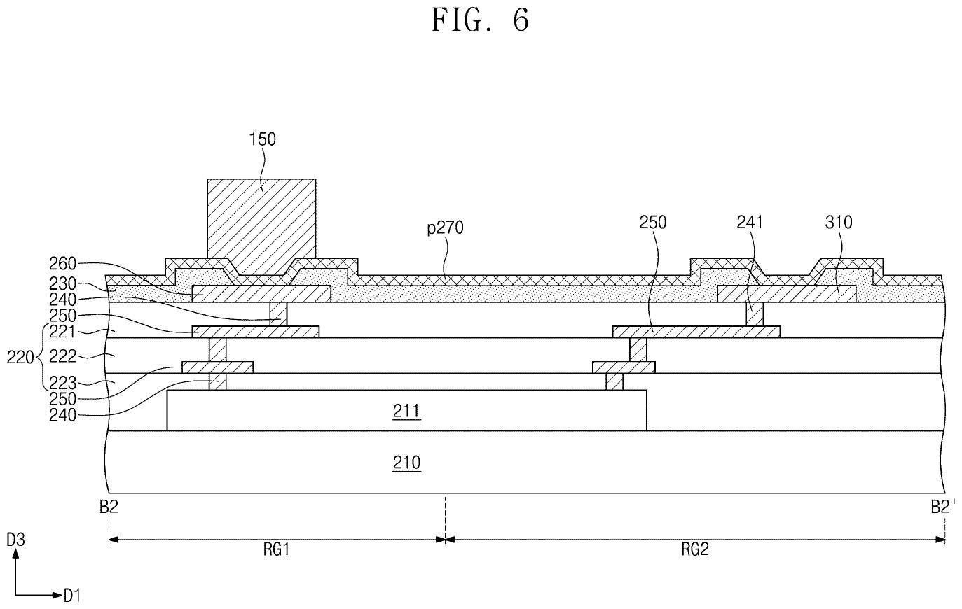

Referring to FIG. 6, the photoresist layer 340 may be removed. The preliminary connection layer p270 may be exposed by removing the photoresist layer 340.

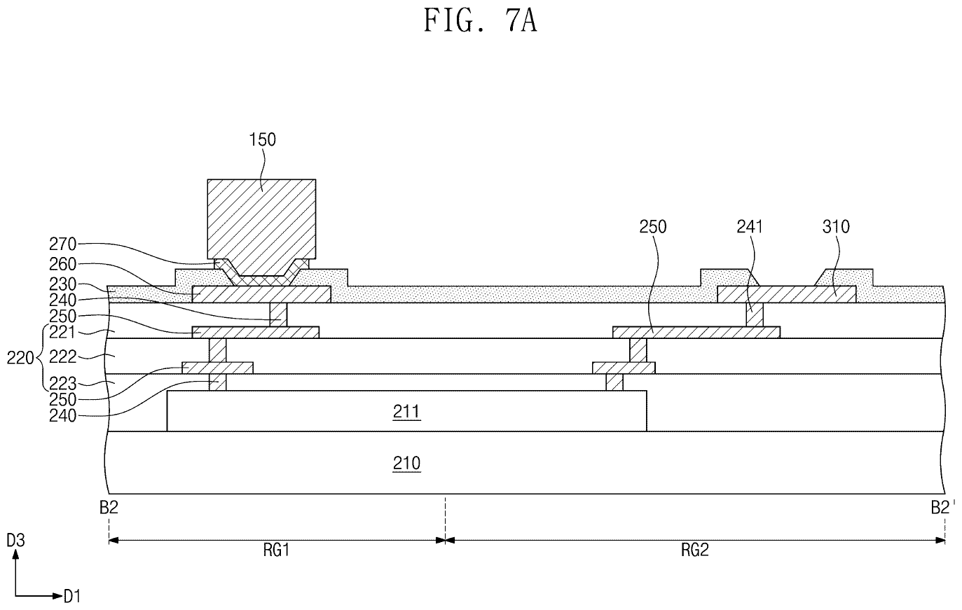

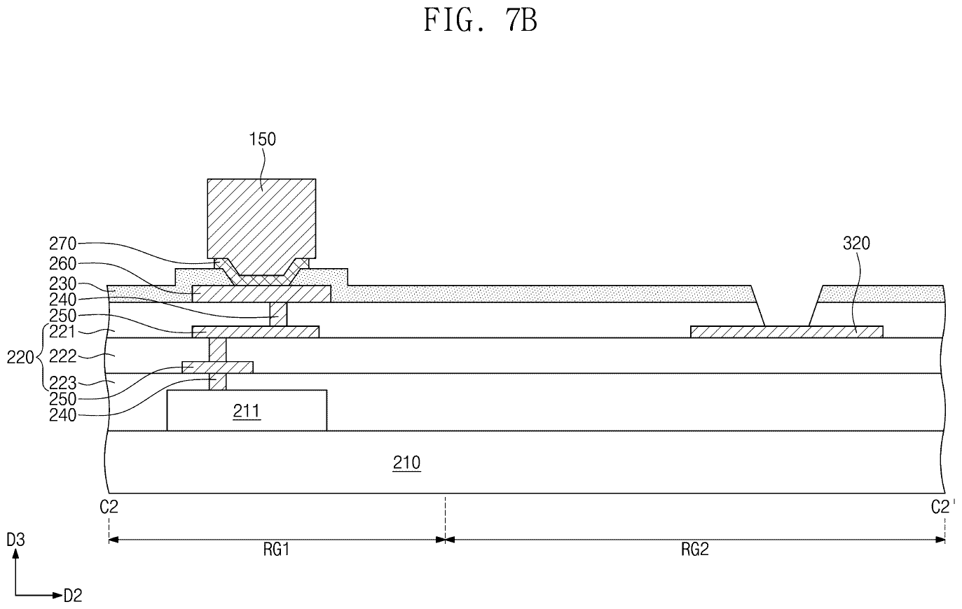

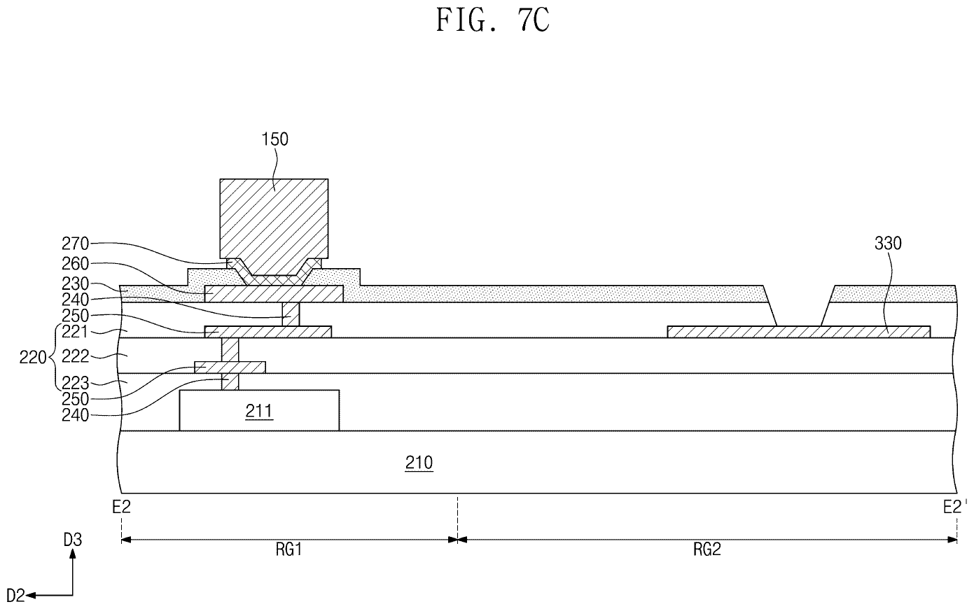

Referring to FIGS. 7A, 7B, and 7C, the preliminary connection layer p270 may be etched. According to some embodiments, an etching process in which the preliminary connection layer p270 may be selectively etched may be performed.

A connection pattern 270 may be formed by etching the preliminary connection layer p270 (FIG. 6). A portion, of the preliminary connection layer p270, overlapping the bump 150 in the third direction D3 may not be etched due to the bump 150 and may be defined as the connection pattern 270.

The test pad 310, the measurement pad 320, and the key pattern 330 may be exposed by etching the preliminary connection layer p270.

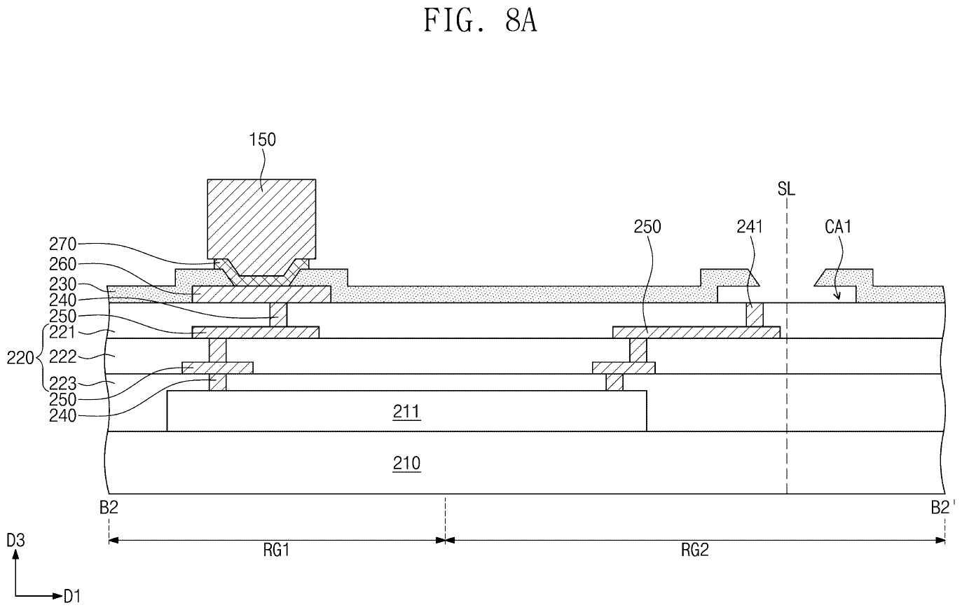

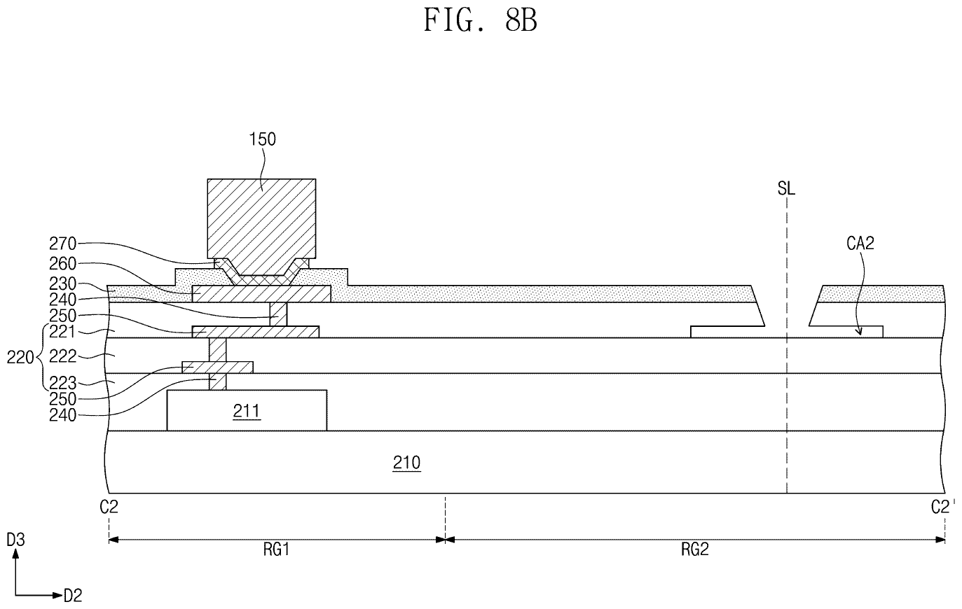

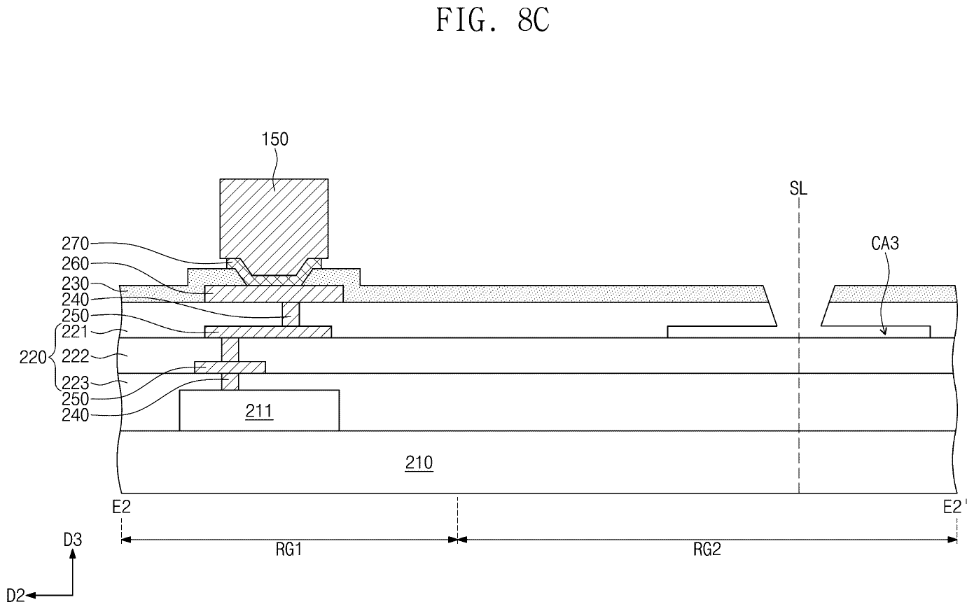

Referring to FIGS. 8A, 8B, and 8C, the test pad 310, the measurement pad 320, and the key pattern 330 may be removed. According to some embodiments, an etching process in which the test pad 310, the measurement pad 320, and the key pattern 330 may be selectively etched may be performed.

A first cavity CA1 may be formed by removing the test pad 310. A second cavity CA2 may be formed by removing the measurement pad 320. A third cavity CA3 may be formed by removing the key pattern 330.

A scribing process may be performed. The scribing process may include cutting the substrate 210 along a scribing line SL. The scribing line SL may overlap the second region RG2 in the third direction D3. The scribing line SL may intersect the first to third cavities CA1, CA2, and CA3. As understood by one of ordinary skill in the art, the scribing process may create a groove in a wafer to break the wafer into individual chips. Scribing may include (i) creating a groove in the wafer using a diamond tool or laser, (ii) applying pressure to the other side of the wafer to expand a crack, and (iii) breaking the wafer into individual chips.

Referring to FIGS. 1A to 1F, a plurality of chips 200 may be formed by performing the scribing process. The chip 200 may be electrically connected to a base structure 100 including a base substrate 110, connection pads 120, and connection lines 130. The chip 200 and the base structure 100 may be electrically connected by forming an adhesive pattern 140 between the bump 150 and the connection line 130.

A filling layer 160 may be formed between the chip 200 and the base structure 100. The filling layer 160 may fill the first to third cavities CA1, CA2, and CA3. A cover layer 170 covering the chip 200 may be formed.

In the method for manufacturing a semiconductor package according to some embodiments, the test pad 310, the measurement pad 320, and the key pattern 330 may be removed before a scribing process is performed. For example, an under bump metallization (UBM) covering a chip pad, the test pad, and the key pattern is formed, and then a bump is formed on the chip pad. Thereafter, when the UBM metal is etched, due to the bump, only the UBM metal on the chip pad remains, and the UBM metal on the test pad and the key pattern is removed. Accordingly, the test pad and the key pattern are exposed. The exposed test pad and key pattern are removed so that there is no metal cut in a subsequent scribing process. Accordingly, a phenomenon in which a burr is generated due to the test pad 310, the measurement pad 320, and the key pattern 330 in the scribing process may be prevented or limited.

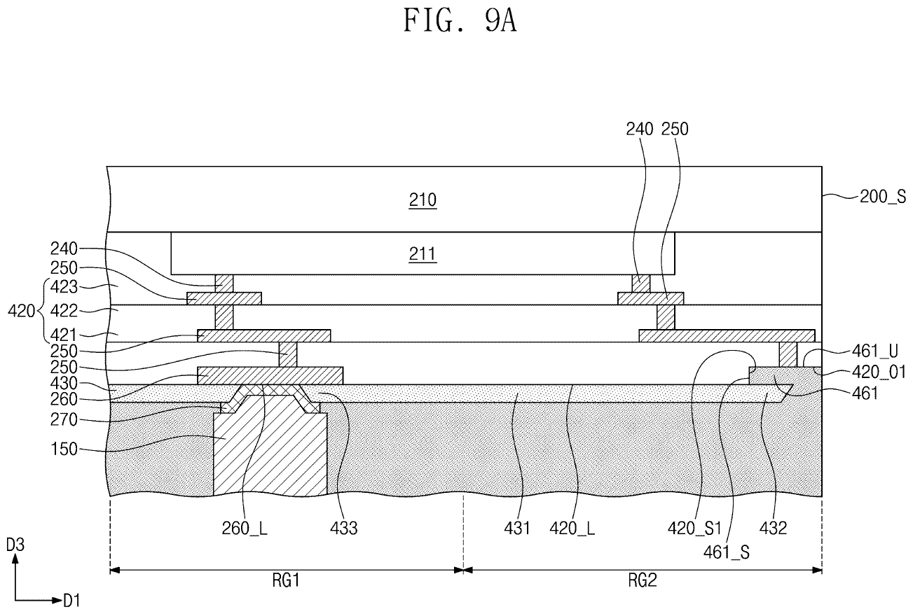

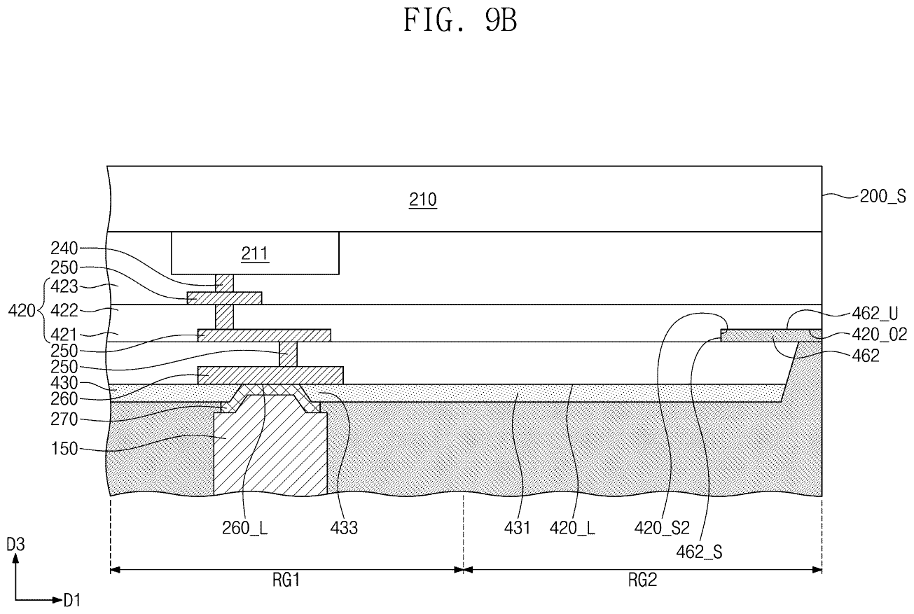

FIGS. 9A and 9B are enlarged cross-sectional views of a semiconductor package according to some embodiments. The semiconductor package according to FIGS. 9A and 9B may be similar to the semiconductor package according to FIGS. 1A to 1F except for the following description.

Referring to FIGS. 9A and 9B, a protective layer 430 may include a first portion 431 being in contact with a lower surface 420_L of an insulating structure 420, a second portion 432 spaced apart from the insulating structure 420 and a conductive pad 260, and a third portion 433 being in contact with a lower surface 260_L of the conductive pad 260. The first to third portions 431, 432, and 433 of the protective layer 430 may be arranged at the same level. Lower surfaces of the first to third portions 431, 432, and 433 of the protective layer 430 may be coplanar with each other. Upper surfaces of the first to third portions 431, 432, and 433 of the protective layer 430 may be coplanar with each other.

The insulating structure 420 may include a first insulating layer 421 on the protective layer 430, a second insulating layer 422 on the first insulating layer 421, and a third insulating layer 423 on the second insulating layer 422. A connection pattern 250 may be in contact with an upper surface of the second insulating layer 422 or an upper surface of the first insulating layer 421. The conductive pad 260 may be provided in the first insulating layer 421.

A filling layer 460 may include a first interposed portion 461 between the second portion 432 of the protective layer 430 and the insulating structure 420. The insulating structure 420 may include a first surface 420_O1 being in contact with an upper surface 461_U of the first interposed portion 461. A level of the first surface 420_O1 of the insulating structure 420 may be higher than a level of the lower surface 420_L of the insulating structure 420.

The insulating structure 420 may include a first sidewall 420_S1 being in contact with a sidewall 461_S of the first interposed portion 461. The first sidewall 420_S1 of the insulating structure 420 may be connected to the first surface 420_O1 of the insulating structure 420 and the lower surface 420_L of the insulating structure 420.

The filling layer 460 may further include a second interposed portion 462 between the first insulating layer 421 and the second insulating layer 422. The insulating structure 420 may include a second surface 420_O2 being in contact with an upper surface 462_U of the second interposed portion 462. A level of the second surface 420_O2 of the insulating structure 420 may be higher than a level of a lower surface of the second insulating layer 422.

The insulating structure 420 may include a second sidewall 420_S2 being in contact with a sidewall 462_S of the second interposed portion 462. The second sidewall 420_S2 of the insulating structure 420 may be connected to the second surface 420_O2 of the insulating structure 420 and a lower surface of the second insulating layer 422.

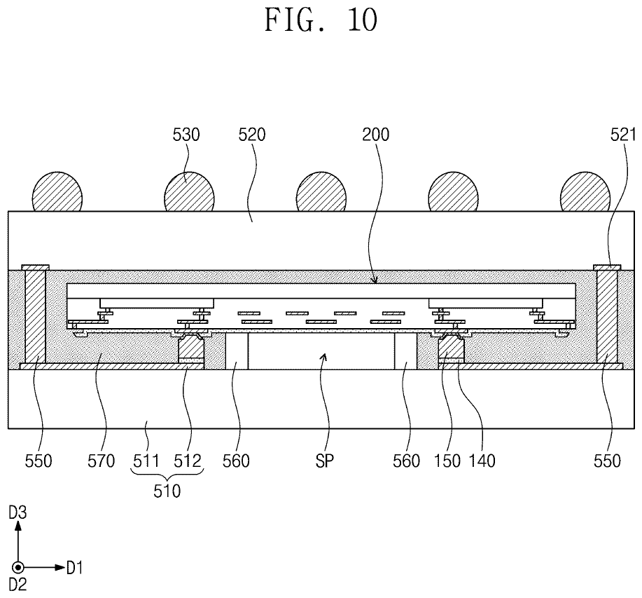

FIG. 10 is a cross-sectional view of a semiconductor package according to some embodiments. The semiconductor package according to FIG. 10 may be similar to the semiconductor package according to FIGS. 1A to 1F except for the following description.

Referring to FIG. 10, the semiconductor package may include a chip 200, bumps 150, adhesive patterns 140, a base structure 510, a package substrate 520, terminals 530, connection pillars 550, a dam 560, and a filling layer 570.

The package substrate 520 may be, for example, a printed circuit board. The package substrate 520 may include connection pads 521.

The terminals 530 may be connected to the package substrate 520. The terminals 530 may include a conductive material. The semiconductor package may be electrically connected to an external device through the terminals 530.

The base structure 510 may include a transparent substrate 511 and connection lines 512. The transparent substrate 511 may include a material having high light transmittance. For example, the transparent substrate 511 may include glass.

The connection lines 512 may be provided on the transparent substrate 511. The chip 200 may be electrically connected to the base structure 510 through the bump 150 and the adhesive pattern 140. The chip 200 may be electrically connected to the connection line 512 of the base structure 510 through the bump 150 and the adhesive pattern 140. The chip 200 may be disposed between the base structure 510 and the package substrate 520.

The connection pillar 550 may electrically connect the connection line 512 and the connection pad 521. The connection pillar 550 may include a conductive material. The chip 200 may be disposed between the connection pillars 550.

The dam 560 may be disposed between the chip 200 and the base structure 510. The dam 560 may surround a partial region of the chip 200 in a plan view. For example, the dam 560 may have a shape of a quadrangular ring. For example, the dam 560 may include a polymer material.

An empty space SP surrounded by the dam 560 may be provided. The empty space SP may be provided between the chip 200 and the base structure 510. According to some embodiments, the chip 200 may include an optical device exposed through the empty space SP.

The filling layer 570 may be provided between the base structure 510 and the package substrate 520. The filling layer 570 may surround the chip 200, the connection pillar 550, and the bump 150. The filling layer 570 may include an interposed portion being in contact with an edge of the chip 200.

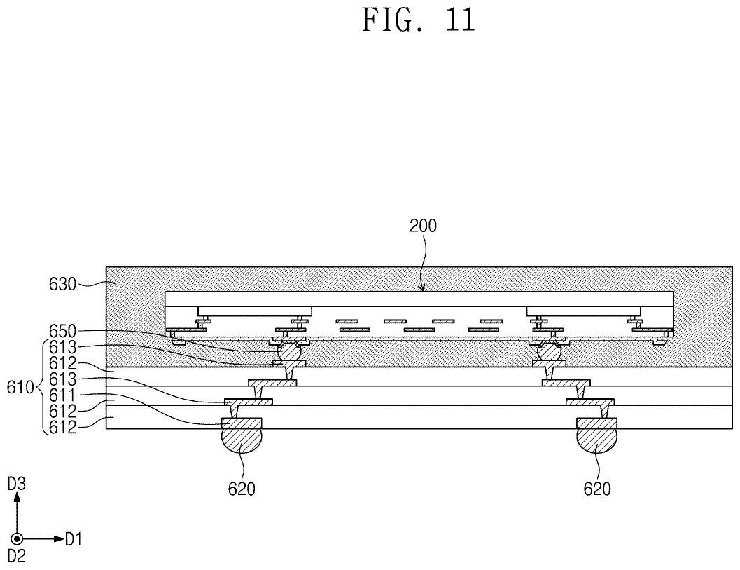

FIG. 11 is a cross-sectional view of a semiconductor package according to some embodiments. The semiconductor package according to FIG. 11 may be similar to the semiconductor package according to FIGS. 1A to 1F except for the following description.

Referring to FIG. 11, the semiconductor package may include a chip 200, bumps 650, a base structure 610, terminals 620, and a filling layer 630.

The base structure 610 may be a redistribution substrate. The base structure 610 may include lower conductive patterns 611, photosensitive insulating layers 612, and redistribution patterns 613.

The photosensitive insulating layers 612 may include a photosensitive insulating material. The photosensitive insulating material may include, for example, at least one of photosensitive polyimide, polybenzoxazole, phenolic polymer, or benzocyclobutene-based polymer.

The lower conductive patterns 611 may be disposed in a lowermost photosensitive insulating layer 612 among the photosensitive insulating layers 612. The terminal 620 may be connected to the lower conductive pattern 611. The terminal 620 and the lower conductive pattern 611 may include a conductive material.

The redistribution patterns 613 may be provided in the photosensitive insulating layers 612. First redistribution patterns 613 may be electrically connected to the lower conductive pattern 611. The redistribution patterns 613 may include a conductive material. The redistribution patterns 613 may include a via portion extending in a vertical direction and a wiring portion extending in a horizontal direction.

According to some embodiments, the base structure 610 may be a printed circuit board.

The chip 200 may be electrically connected to the redistribution pattern 613 of the base structure 610 through the bump 650.

The filling layer 630 may be provided on the base structure 610. The filling layer 630 may surround the chip 200 and the bump 650. The filling layer 630 may include an interposed portion being in contact with an edge of the chip 200.

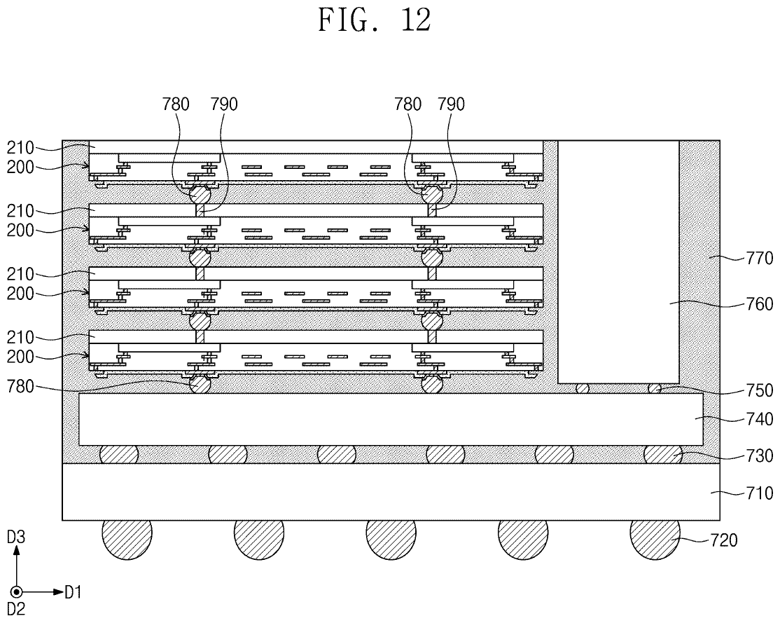

FIG. 12 is a cross-sectional view of a semiconductor package according to some embodiments. The semiconductor package according to FIG. 12 may be similar to the semiconductor package according to FIGS. 1A to 1F except for the following description.

Referring to FIG. 12, the semiconductor package may include chips 200, bumps 780, a base structure 740, a package substrate 710, first terminals 720, second terminals 730, third terminals 750, a processor chip 760, and a filling layer 770.

The package substrate 710 may be, for example, a printed circuit board. The first terminals 720 electrically connected to the package substrate 710 may be provided. The semiconductor package may be mounted on an external device (for example, a main board) through the first terminals 720.

The base structure 740 may be provided above the package substrate 710. The base structure 740 may be, for example, a silicon interposer. The second terminals 730 electrically connecting the package substrate 710 and the base structure 740 may be provided. The second terminals 730 may be provided between the package substrate 710 and the base structure 740.

The processor chip 760 may be provided above the base structure 740. For example, the processor chip 760 may be a graphic processing unit (GPU) or a central processing unit (CPU). The third terminals 750 electrically connecting the processor chip 760 and the base structure 740 may be provided. The third terminals 750 may be provided between the processor chip 760 and the base structure 740.

The chips 200 sequentially arranged above the base structure 740 along the third direction D3 may be provided. The bumps 780 may be provided between the base structure 740 and the chip 200, and between the chips 200. The chip 200 may be electrically connected to the base structure 740 through the bump 780.

The chips 200 excluding an uppermost chip 200 may include a through via 790. The through via 790 may penetrate a substrate 210 of the chip 200 in the third direction D3. The through via 790 may be electrically connected to the bump 780. According to some embodiments, a pad may be provided between the through via 790 and the bump 780 and electrically connect the through via 790 and the bump 780. The through via 790 may include a conductive material.

The filling layer 770 may be provided on the package substrate 710. The filling layer 770 may surround the base structure 740, the chips 200, the processor chip 760, and the bumps 780. The filling layer 770 may include an interposed portion being in contact with an edge of the chip 200.

In a semiconductor package according to embodiments of the present disclosure, a conductive pad or a conductive pattern may be prevented from being disposed at an edge of a chip, and a phenomenon in which a burr is generated due to arrangement of a conductive pad or a conductive pattern at the edge of the chip may be prevented.

Although embodiments of the present disclosure have been described with reference to the accompanying drawings, those of ordinary skill in the art could understand that the present disclosure can be carried out in other specific forms without changing the technical concept or essential features. Therefore, the above embodiments should be considered illustrative and should not be construed as limiting.

What is claimed is:

1. A semiconductor package comprising:
a base structure;
a bump connected to the base structure;
a chip connected to the bump; and
a filling layer surrounding the bump,
wherein the chip comprises:
a substrate,
an insulating structure between the substrate and the bump,
a protective layer between the bump and the insulating structure,
a conductive pad between the protective layer and the insulating structure, and
a connection pattern penetrating the protective layer and connecting the bump and the conductive pad, and
wherein the filling layer comprises an interposed portion between the protective layer and the insulating structure.

2. The semiconductor package of claim 1, wherein the insulating structure comprises a surface in contact with a first surface of the interposed portion, and
wherein the protective layer comprises a surface in contact with a second surface of the interposed portion.

3. The semiconductor package of claim 2, wherein the insulating structure comprises a sidewall in contact with a sidewall of the interposed portion.

4. The semiconductor package of claim 2, wherein the protective layer comprises a sidewall in contact with a sidewall of the interposed portion.

5. The semiconductor package of claim 1, wherein the protective layer comprises (i) a first portion in contact with the insulating structure and (ii) a second portion spaced apart from the insulating structure, and
wherein the interposed portion is interposed between the second portion of the protective layer and the insulating structure.

6. The semiconductor package of claim 5, wherein the second portion of the protective layer is at a level below the first portion of the protective layer.

7. The semiconductor package of claim 6, wherein a sidewall of the interposed portion is in contact with a sidewall of the first portion of the protective layer, and
a surface of the interposed portion is in contact with a surface of the second portion of the protective layer.

8. The semiconductor package of claim 1, wherein the interposed portion is at a same level as the conductive pad.

9. A semiconductor package comprising:
a base structure;
a bump connected to the base structure; and
a chip connected to the bump,
wherein the chip comprises:
a substrate,
an insulating structure between the substrate and the bump,
a protective layer between the bump and the insulating structure,
a conductive pad between the protective layer and the insulating structure, and
a connection pattern penetrating the protective layer and connecting the bump and the conductive pad,
wherein the protective layer comprises a first portion, and a second portion and a third portion spaced apart from each other with the first portion therebetween,
wherein a surface of the first portion of the protective layer is in contact with a surface of the insulating structure,
wherein a surface of the third portion of the protective layer is in contact with a surface of the conductive pad, and
wherein a surface of the second portion of the protective layer is spaced apart from the insulating structure and the conductive pad.

10. The semiconductor package of claim 9, wherein a first distance between the second portion of the protective layer and a sidewall of the chip is smaller than a second distance between the third portion of the protective layer and the sidewall of the chip.

11. The semiconductor package of claim 9, further comprising a filling layer surrounding the bump,
wherein the filling layer comprises a first interposed portion between the second portion of the protective layer and the insulating structure.

12. The semiconductor package of claim 11, wherein the chip further comprises a conductive via in contact with the first interposed portion, and
a surface of the conductive via is coplanar with the surface of the insulating structure.

13. The semiconductor package of claim 11, wherein the insulating structure comprises:
a first insulating layer in contact with the protective layer; and
a second insulating layer in contact with the first insulating layer and spaced apart from the protective layer, and
the filling layer further comprises a second interposed portion between the first insulating layer and the second insulating layer.

14. The semiconductor package of claim 13, wherein the first insulating layer comprises:
a surface in contact with a surface of the second interposed portion; and
a sidewall connected to the surface of the first insulating layer, and
the sidewall of the first insulating layer is inclined with respect to the surface of the insulating structure.

15. The semiconductor package of claim 14, wherein the protective layer comprises a sidewall that is coplanar with the sidewall of the first insulating layer, and
the sidewall of the protective layer is inclined with respect to the surface of the insulating structure.

16. A semiconductor package comprising:
a base structure;
a bump connected to the base structure;
a chip connected to the bump; and
a filling layer surrounding the bump,
wherein the chip comprises:
a substrate,
an insulating structure between the substrate and the bump,
a semiconductor device between the substrate and the insulating structure,
a conductive via connected to the semiconductor device,
a conductive pad in contact with the conductive via,
a protective layer in contact with the insulating structure and the conductive pad, and
a connection pattern penetrating the protective layer and in contact with the bump and the conductive pad,
wherein the protective layer comprises a first portion in contact with a surface of the insulating structure and a second portion spaced apart from the insulating structure, and
wherein the filling layer comprises:
a first interposed portion in contact with a surface of the second portion of the protective layer, and
a first connection portion in contact with a sidewall of the second portion of the protective layer.

17. The semiconductor package of claim 16, wherein a width of the protective layer is smaller than a width of the insulating structure.

18. The semiconductor package of claim 16, wherein the insulating structure comprises:
a first insulating layer in contact with the protective layer; and
a second insulating layer in contact with the first insulating layer and spaced apart from the protective layer, and
wherein the filling layer further comprises:
a second interposed portion between the first insulating layer and the second insulating layer, and
a second connection portion in contact with a sidewall of the first insulating layer and a sidewall of the protective layer.

19. The semiconductor package of claim 18, wherein a surface of the second interposed portion is in contact with the second insulating layer, and
a surface of the second interposed portion is in contact with the first insulating layer.

20. The semiconductor package of claim 18, wherein a first distance between the second interposed portion and the substrate is smaller than a second distance between the first interposed portion and the substrate.
